(19) United States
(12) Patent Application Publication
(10) Pub. No.: US 2010/0047959 A1
(43) Pub. Date: Feb. 25, 2010

(54) Epitaxial Lift Off on Film Mounted Inverted Metamorphic Multijunction Solar Cells

(75) Inventors: Arthur Cornfeld, Sandia Park, NM (US); Daniel McGlynn, Albuquerque, NM (US); Tansen Varghese, Albuquerque, NM (US)

Correspondence Address: EMCORE CORPORATION, 1600 EUBANK BLVD, S.E., ALBUQUERQUE, NM, 87123, US

(73) Assignee: EMCORE SOLAR POWER, INC., Albuquerque, NM (US)

(21) Appl. No.: 12/607,554

(22) Filed: Oct. 28, 2009

Related U.S. Application Data
(63) Continuation-in-part of application No. 11/500,053, filed on Aug. 7, 2006.
Application No. 11/500,053 is a continuation-in-part of application No. 12/367,991, filed on Feb. 9, 2009.

(51) Int. Cl. H01L 31/18; H01L 21/20

(52) U.S. Cl. 438/94; 438/455; 257/E21.09

(57) ABSTRACT

A process for selectively freeing an epitaxial layer from a single crystal substrate upon which it was grown, by providing a first substrate; depositing a separation layer on the first substrate; depositing on the separation layer a sequence of layers of semiconductor material forming a solar cell; mounting and bonding a thin flexible support having a coefficient of thermal expansion substantially greater than that of the adjacent semiconductor material on top of the sequence of layers at an elevated temperature; and etching the separation layer while the temperature of the support and layers of semiconductor material decrease, so that the support and the attached layer curls away from the first substrate in view of their differences in coefficient of thermal expansion, so as to remove the epitaxial layer from the substrate.

### REFERENCE TO RELATED APPLICATIONS

This application is a continuation-in-part of co-pending U.S. patent application Ser. No. 11/500,053 filed Aug. 7, 2006, and co-pending U.S. patent application Ser. No. 12/367,991, filed Feb. 9, 2009.

This application is related to co-pending U.S. patent application Ser. No. 12/544,001, filed Aug. 19, 2009.

This application is related to co-pending U.S. patent application Ser. Nos. 12/401,137, 12/401,157, and 12/401,189, filed Mar. 10, 2009.

This application is related to co-pending U.S. patent application Ser. No. 12/389,053, filed Feb. 19, 2009.

This application is related to co-pending U.S. patent application Ser. No. 12/362,201, Ser. No. 12/362,213, and Ser. No. 12/362,225 filed Jan. 29, 2009.

This application is related to co-pending U.S. patent application Ser. No. 12/337,014 and Ser. No. 12/337,043 filed Dec. 17, 2008.

This application is related to co-pending U.S. patent application Ser. No. 12/271,127 and Ser. No. 12/271,192 filed Nov. 14, 2008.

This application is related to co-pending U.S. patent application Ser. No. 12/267,812 filed Nov. 10, 2008.

This application is related to co-pending U.S. patent application Ser. No. 12/258,190 filed Oct. 24, 2008.

This application is related to co-pending U.S. patent application Ser. No. 12/253,051 filed Oct. 16, 2008.

This application is related to co-pending U.S. patent application Ser. No. 12/190,449, filed Aug. 12, 2008.

This application is related to co-pending U.S. patent application Ser. No. 12/187,477, filed Aug. 7, 2008.

This application is related to co-pending U.S. patent application Ser. No. 12/218,558 and U.S. patent application Ser. No. 12/218,582 filed Jul. 16, 2008.

This application is related to co-pending U.S. patent application Ser. No. 12/123,864 filed May 20, 2008.

This application is related to co-pending U.S. patent application Ser. No. 12/102,550 filed Apr. 14, 2008.

This application is related to co-pending U.S. patent application Ser. No. 12/047,842, and U.S. Ser. No. 12/047,944, filed Mar. 13, 2008.

This application is related to co-pending U.S. patent application Ser. No. 12/023,772, filed Jan. 31, 2008.

This application is related to co-pending U.S. patent application Ser. No. 11/956,069, filed Dec. 13, 2007.

This application is also related to co-pending U.S. patent application Ser. Nos. 11/860,142 and 11/860,183 filed Sep. 24, 2007.

This application is also related to co-pending U.S. patent application Ser. No. 11/836,402 filed Aug. 8, 2007.

This application is also related to co-pending U.S. patent application Ser. No. 11/616,596 filed Dec. 27, 2006.

This application is also related to co-pending U.S. patent application Ser. No. 11/614,332 filed Dec. 21, 2006.

This application is also related to co-pending U.S. patent application Ser. No. 11/445,793 filed Jun. 2, 2006.

### GOVERNMENT RIGHTS STATEMENT

This invention was made with government support under Contract No. FA9453-06-C-0345 awarded by the U.S. Air Force. The Government has certain rights in the invention.

### BACKGROUND OF THE INVENTION

1. Field of the Invention

The present invention relates to the field of semiconductor devices, and to fabrication processes and devices such as multifunction solar cells based on III-V semiconductor compounds including a metamorphic layer. Some examples of such devices grown in a reverse sequence are known as inverted metamorphic multifunction solar cells.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multifunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multifunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

Inverted metamorphic solar cell structures based on III-V compound semiconductor layers, such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), present an important conceptual starting point for the development of future commercial high efficiency solar cells. However, the materials and structures for a number of different layers of the cell proposed and described in such reference present a number of practical difficulties, particularly relating to the most appropriate choice of materials and fabrication steps.

Prior to the inventions described in this and the related applications noted above, the materials and fabrication steps disclosed in the prior art have not been adequate to produce a commercially viable and energy efficient inverted metamorphic multijunction solar cell using commercially established fabrication processes.

### SUMMARY OF THE INVENTION

Briefly, and in general terms, the present invention provides a process for selectively freeing an epitaxial layer from a single crystal substrate upon which it was grown, by providing a first substrate; depositing a separation layer on the first substrate; depositing on the separation layer a sequence of layers of semiconductor material forming a solar cell; mounting and bonding a thin flexible support having a coefficient of thermal expansion substantially greater than that of the adjacent semiconductor material on top of the sequence of layers at an elevated temperature; and etching the separation layer while the temperature of the support and layers of semiconductor material decrease, so that the support and the attached layer curls away from the first substrate in view of the differences in coefficient of thermal expansion of the support and the semiconductor layers, so as to remove the epitaxial layer from the substrate.

In another aspect the present invention provides a method for selectively freeing an epitaxial layer from a single crystal substrate upon which it was grown, by providing a substrate; depositing a separation layer on the substrate; depositing on the separation layer a sequence of epitaxial layers of semiconductor material forming a semiconductor device; mounting and bonding a thin flexible support on top of the sequence of layers; and subsequently processing the substrate at decreasing temperature so that the difference in the coefficient of thermal expansion of the thin flexible support and the semiconductor material results in the curling back of the thin flexible support and the layers of semiconductor material as they separate from the substrate.

In another aspect the present invention provides a process for selectively freeing an epitaxial layer from a single crystal substrate upon which it was grown, by providing a first substrate; depositing a separation layer on the substrate; depositing on the separation layer a sequence of layers of semiconductor material forming a semiconductor device; mounting and bonding a thin flexible support on top of the sequence of layers at an elevated temperature; and etching the separation layer while the support is cooled to room temperature so as to remove the epitaxial layer from the substrate.

In another aspect the present invention provides a process for selectively freeing an epitaxial layer from a single crystal substrate upon which it was grown, by providing a substrate; depositing a separation layer on the substrate; depositing on the separation layer a sequence of layers of semiconductor material forming a semiconductor device; mounting and bonding a thin flexible support on top of the sequence of layers at a temperature over 150 degrees C.; and etching the separation layer while the support and semiconductor material is cooled to room temperature, so that the difference in the coefficient of thermal expansion of the thin flexible support and the semiconductor material results in the curling back of the thin flexible support and the layers of semiconductor material as they separate from the substrate.

Some implementations of the present invention may incorporate or implement fewer of the aspects and features noted in the foregoing summaries.

Additional aspects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

FIG. 2 is a cross-sectional view of the solar cell of the invention after the deposition of semiconductor layers on the growth substrate;

FIG. 3 is a cross-sectional view of the solar cell of FIG. 2 after the next process step;

FIG. 4 is a cross-sectional view of the solar cell of FIG. 3 after the next process step in which a flexible support is attached;

FIG. 5 is a cross-sectional view of a first method of epitaxial lift off known in the prior art;

FIG. 6 is a cross-sectional view of a second method of epitaxial lift off known in the prior art;

FIG. 7 is an enlarged cross-sectional view of the solar cell during the process of epitaxial lift off according to the present invention;

FIG. 8A is a cross-sectional view of the solar cell of FIG. 7 after the epitaxial lift off step in which the epitaxy has been removed from the original substrate;

FIG. 8B is a cross-sectional view of the solar cell of FIG. 8A with the surrogate substrate depicted on the bottom of the Figure;

FIG. 9 is a simplified cross-sectional view of the solar cell of FIG. 8B;

FIG. 10 is a cross-sectional view of the solar cell of FIG. 9 after the next process step;

FIG. 11 is a cross-sectional view of the solar cell of FIG. 10 after the next process step;

FIG. 12A is a top plan view of a wafer in which four solar cells are fabricated;

FIG. 12B is a bottom plan view of the wafer of FIG. 12A;

FIG. 12C is a top plan view of a wafer in which two solar cells are fabricated;

FIG. 13 is a cross-sectional view of the solar cell of FIG. 11 after the next process step;

FIG. 14A is a cross-sectional view of the solar cell of FIG. 13 after the next process step;

FIG. 14B is a cross-sectional view of the solar cell of FIG. 14A after the next process step;

FIG. 15A is a top plan view of the wafer of FIG. 12A depicting the surface view of the trench etched around the cell, after the next process step;

FIG. 15B is a cross-sectional view of the solar cell of FIG. 12C depicting the trench etched around the cell;

FIG. 16A is a cross-sectional view of the solar cell of FIG. 14B after the next process step in a first embodiment of the present invention;

FIG. 16B is a cross-sectional view of the solar cell of FIG. 16B after the next process step in a third embodiment of the present invention in which a cover glass is applied to the top of the cell;

FIG. 16C is a cross-sectional view of the solar cell of FIG. 16A after the next process step in an embodiment of the present invention in which the surrogate substrate is removed;

FIG. 17 is a cross-sectional view of the solar cell of FIG. 18D after the next process step in which a cover glass is applied to the top of the cell;

FIG. 18 is a graph of the doping profile in the base and emitter layers of a subcell in the metamorphic solar cell according to the present invention;

FIG. 19 is a graph that depicts the current and voltage characteristics of an inverted metamorphic multifunction solar cell according to the present invention.

### DESCRIPTION OF THE PREFERRED EMBODIMENT

Details of the present disclosure will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The basic concept of fabricating an inverted metamorphic multijunction (IMM) solar cell is to grow the subcells of the solar cell on a substrate in a “reverse” sequence. That is, the high band gap subcells (i.e. subcells with band gaps in the range of 1.8 to 2.1 eV), which would normally be the “top” subcells facing the solar radiation, are initially grown epitaxially directly on a semiconductor growth substrate, such as for example GaAs or Ge, and such subcells are consequently lattice-matched to such substrate. One or more lower band gap middle subcells (i.e. with band gaps in the range of 1.2 to 1.8 eV) can then be grown on the high band gap subcells.

At least one lower subcell is formed over the middle subcell such that the at least one lower subcell is substantially lattice-mismatched with respect to the growth substrate and such that the at least one lower subcell has a third lower band gap (i.e., a band gap in the range of 0.7 to 1.2 eV). A surrogate substrate or support structure is then attached or provided over the “bottom” or substantially lattice-mismatched lower subcell, and the growth semiconductor substrate is subsequently removed. (The growth substrate may then subsequently be re-used for the growth of a second and subsequent solar cells). In the present disclosure, the support structure is a flexible film.

A variety of different features and aspects of inverted metamorphic multifunction solar cells are disclosed in the related applications noted above. Some or all of such features may be included in the structures and processes associated with the solar cells of the present disclosure. More particularly, one aspect of the present application is directed to the method of depositing a separation layer over the growth substrate, depositing the epitaxial layers forming a solar cell over the separation layer, mounting the epitaxial layers on a flexible substrate, and removing the separation layer to release the epitaxial layers. None, some or all of such aspects may be included in the structures and processes associated with the solar cells of the present disclosure.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It should be apparent to one skilled in the art that the inclusion of additional semiconductor layers within the cell with similar or additional functions and properties is also within the scope of the present disclosure.

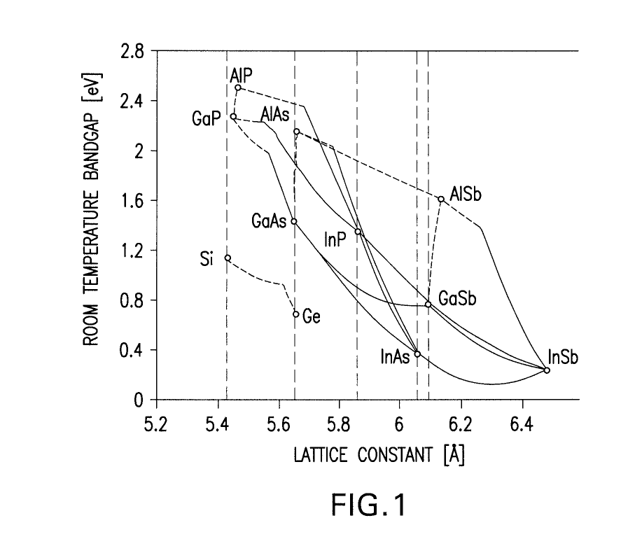

FIG. 1 is a graph representing the band gap of certain binary materials and their lattice constants. The band gap and lattice constants of ternary materials are located on the lines drawn between typical associated binary materials (such as the ternary material GaAlAs being located between the GaAs and AlAs points on the graph, with the band gap of the ternary material lying between 1.42 eV for GaAs and 2.16 eV for AlAs depending upon the relative amount of the individual constituents). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), Molecular Beam Epitaxy (MBE), or other vapor deposition methods for the reverse growth may enable the layers in the monolithic semiconductor structure forming the cell to be grown with the required thickness, elemental composition, dopant concentration and grading and conductivity type.

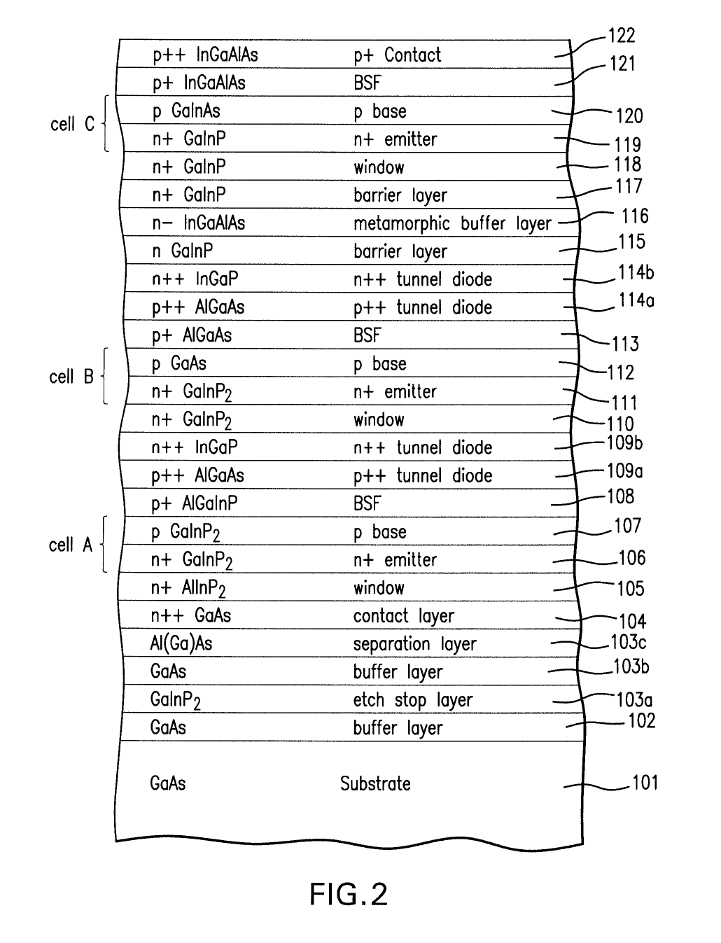

FIG. 2 depicts the multifunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111)A plane, as more fully described in U.S. patent application Ser. No. 12/047,944, filed Mar. 13, 2008. Other alternative growth substrates, such as described in U.S. patent application Ser. No. 12/337,014 filed Dec. 17, 2008, maybe used as well.

In the case of a Ge substrate, a nucleation layer (not shown) is deposited directly on the substrate 101. On the substrate, or over the nucleation layer (in the case of a Ge substrate), a buffer layer 102 and an etch stop layer 103a are further deposited. In the case of GaAs substrate, the buffer layer 102 is preferably GaAs. In the case of Ge substrate, the buffer layer 102 is preferably InGaAs. On top of the etch stop layer, a buffer layer 103b of GaAs is deposited. On top of the buffer layer 103b, a thin separation layer 103c of Al(Ga) is deposited. The layer 103c is typically about 100 Angstroms in thickness. A contact layer 104 of GaAs is then deposited on layer 103c, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multifunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 according to the present invention will be discussed in conjunction with FIG. 20.

Subcell A will ultimately become the “top” subcell of the inverted metamorphic structure after completion of the process steps according to the present invention to be described hereinafter.

On top of the base layer 107 a back surface field (“BSF”) layer 108 preferably p+ AlGaInP is deposited and used to reduce recombination loss.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109a and 109b that forms a tunnel diode, i.e. an ohmic circuit element that connects subcell A to subcell B. Layer 109a is preferably composed of p++ AlGaAs, and layer 109b is preferably composed of n++ InGaP.

On top of the tunnel diode layers 109 a window layer 110 is deposited, preferably n+ InGaP. The advantage of utilizing InGaP as the material constituent of the window layer 110 is that it has an index of refraction that closely matches the adjacent emitter layer 111, as more fully described in U.S. patent application Ser. No. 12/258,190, filed Oct. 24, 2008. More generally, the window layer 110 used in the subcell B operates to reduce the interface recombination loss. It should be apparent to one skilled in the art, that additional layer(s) may be added or deleted in the cell structure without departing from the scope of the present invention.

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to the present invention will be discussed in conjunction with FIG. 20.

In previously disclosed implementations of an inverted metamorphic solar cell, the middle cell was a homostructure. In the present disclosure, similarly to the structure disclosed in U.S. patent application Ser. No. 12/023,772, the middle subcell becomes a heterostructure with an InGaP emitter and its window is converted from InAlP to InGaP. This modification eliminated the refractive index discontinuity at the window/emitter interface of the middle sub-cell. Moreover, the window layer 110 is preferably doped three times that of the emitter 111 to move the Fermi level up closer to the conduction band and therefore create band bending at the window/emitter interface which results in constraining the minority carriers to the emitter layer.

In the preferred embodiment of the present disclosure, the middle subcell emitter has a band gap equal to the top subcell emitter, and the bottom subcell emitter has a band gap greater than the band gap of the base of the middle subcell. Therefore, after fabrication of the solar cell, and implementation and operation, neither the emitters of middle subcell B nor the bottom subcell C will be exposed to absorbable radiation. Substantially all of the photons representing absorbable radiation will be absorbed in the bases of cells B and C, which have narrower band gaps than the emitters. Therefore, the advantages of using heterojunction subcells are: (i) the short wavelength response for both subcells will improve, and (ii) the bulk of the radiation is more effectively absorbed and collected in the narrower band gap base. The effect will be to increase the short circuit current J_{sc}.

On top of the cell B is deposited a BSF layer 113 which performs the same function as the BSF layer 109. The p++/n++ tunnel diode layers 114a and 114b respectively are deposited over the BSF layer 113, similar to the layers 109a and 109b, forming an ohmic circuit element to connect subcell B to subcell C. The layer 114a is preferably composed of p++ Al GaAs, and layer 114b is preferably composed of n++ InGaP.

A barrier layer 115, preferably composed of n-type InGa(Al)P, is deposited over the tunnel diode 114a/114b, to a thickness of about 1.0 micron. Such barrier layer is intended to prevent threading dislocations from propagating, either opposite to the direction of growth into the middle and top subcells A and B, or in the direction of growth into the bottom subcell C, and is more particularly described in copending U.S. patent application Ser. No. 11/860,183, filed Sep. 24, 2007.

A metamorphic layer (or graded interlayer) 116 is deposited over the barrier layer 115 using a surfactant. Layer 116 is preferably a compositionally step-graded series of InGaAlAs layers, preferably with monotonically changing lattice constant, so as to achieve a gradual transition in lattice constant in the semiconductor structure from subcell B to subcell C while minimizing threading dislocations from occurring. The band gap of layer 116 is constant throughout its thickness, preferably approximately equal to 1.5 eV, or otherwise consistent with a value slightly greater than the base band gap of the middle subcell B. The preferred embodiment of the graded interlayer may also be expressed as being composed of (InₓGa₁₋ₓ)_{y} Al_{1-y}As, with x and y selected such that the band gap of the interlayer remains constant at approximately 1.50 eV or other appropriate band gap.

In the surfactant assisted growth of the metamorphic layer 116, a suitable chemical element is introduced into the reactor during the growth of layer 116 to improve the surface characteristics of the layer. In the preferred embodiment, such element may be a dopant or donor atom such as selenium (Se) or tellurium (Te). Small amounts of Se or Te are therefore incorporated in the metamorphic layer 116, and remain in the finished solar cell. Although Se or Te are the preferred n-type dopant atoms, other non-isoelectronic surfactants may be used as well.

Surfactant assisted growth results in a much smoother or planarized surface. Since the surface topography affects the bulk properties of the semiconductor material as it grows and the layer becomes thicker, the use of the surfactants minimizes threading dislocations in the active regions, and therefore improves overall solar cell efficiency.

As an alternative to the use of non-isoelectronic surfactants one may use an isoelectronic surfactant. The term “isoelectronic” refers to surfactants such as antimony (Sb) or bismuth (Bi), since such elements have the same number of valence electrons as the P atom of InGaP, or the As atom in InGaAlAs, in the metamorphic buffer layer. Such Sb or Bi surfactants will not typically be incorporated into the metamorphic layer 116.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In the preferred embodiment of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs is that arsenide-based semiconductor material is much easier to process in standard commercial MOCVD reactors, while the small amount of aluminum assures radiation transparency of the metamorphic layers.

Although the preferred embodiment of the present disclosure utilizes a plurality of layers of InGaAlAs for the metamorphic layer 116 for reasons of manufacturability and radiation transparency, other embodiments of the present disclosure may utilize different material systems to achieve a change in lattice constant from subcell B to subcell C. Thus, the system of Wanlass using compositionally graded InGaP is another embodiment of the present disclosure. Other embodiments of the present disclosure may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

In another embodiment of the present disclosure, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present disclosure.

On top of the window layer 118, the layers of cell C are deposited: the n+ emitter layer 119, and the p-type base layer 120. These layers are preferably composed of n+ type InGaAs and p type InGaAs respectively, or n+ type InGaP and p type InGaAs for a heterojunction subcell, although another suitable materials consistent with lattice constant and bandgap requirements may be used as well. The doping profile of layers 119 and 120 will be discussed in connection with FIG. 20.

A BSF layer 121, preferably composed of InGaAlAs, is then deposited on top of the cell C, the BSF layer performing the same function as the BSF layers 108 and 113.

Finally a high band gap contact layer 122, preferably composed of InGaAlAs, is deposited on the BSF layer 121.

This contact layer added to the bottom (non-illuminated) side of a lower band gap photovoltaic cell, in a single or a multifunction photovoltaic cell, can be formulated to reduce absorption of the light that passes through the cell, so that (1) an ohmic metal contact layer below (non-illuminated side) it will also act as a mirror layer, and (2) the contact layer doesn't have to be selectively etched off, to prevent absorption.

It should be apparent to one skilled in the art that additional layer(s) may be added or deleted in the cell structure without departing from the scope of the present disclosure.

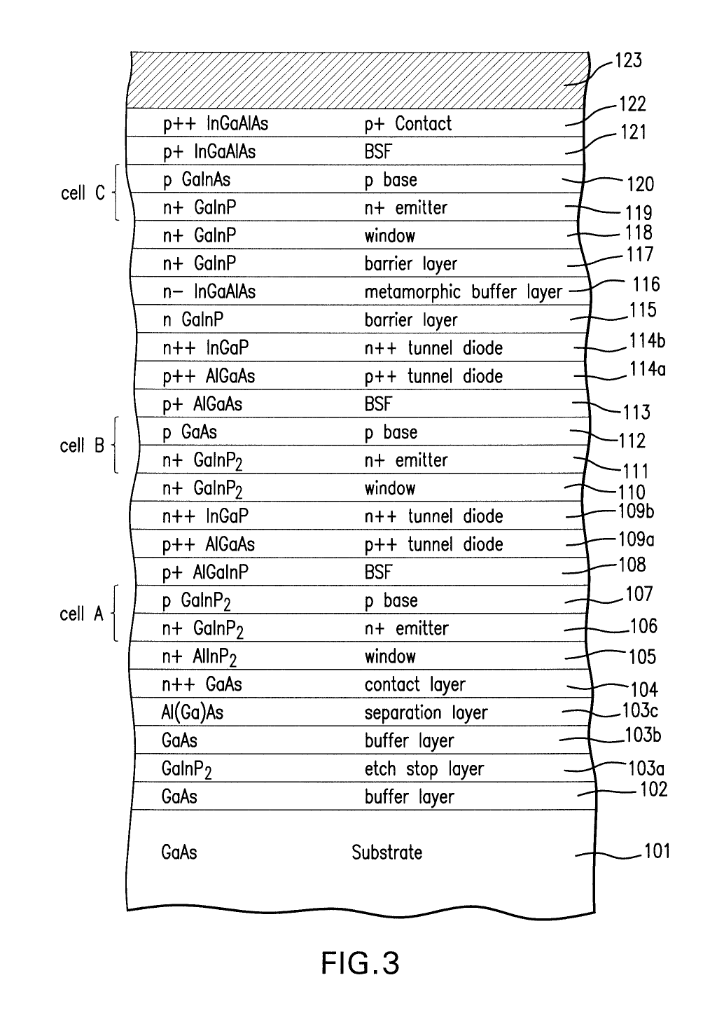

FIG. 3 is a cross-sectional view of the solar cell of FIG. 2 after the next process step in which a metal contact layer 123 is deposited over the p+ semiconductor contact layer 122. As noted in U.S. patent application Ser. No. 12/544,001, filed Aug. 19, 2009, during subsequent processing steps, the semiconductor body and its associated metal layers and bonded structures will go through various heating and cooling processes, which may put stress on the surface of the semiconductor body. Accordingly, it is desirable to closely match the coefficient of thermal expansion of the associated layers or structures to that of the semiconductor body, while still maintaining appropriate electrical conductivity and structural properties of the layers or structures. Thus, in some embodiments, the metal contact layer 123 is selected to have a coefficient of thermal expansion substantially similar to that of the adjacent semiconductor, i.e. in relative terms, within a range of 0 to 10 ppm per degree Kelvin different from that of the adjacent semiconductor material; or in the case of the semiconductor materials described above, in absolute terms a coefficient of thermal expansion equal to around 5 to 7 ppm per degree Kelvin. A variety of metallic compositions and multilayer structures including the element molybdenum would satisfy such criteria. In some embodiments, the layer 123 would preferably include the sequence of metal layers Ti/Au/Mo/Ag/Au, Ti/Au/Mo/Ag, or Ti/Mo/Ag, although other suitable sequences and material compositions may be used as well. In other embodiments, the metal composition may be the sequence of metal layers Ti/Au/Ag/Au or Ti/Pd/Ag, although other suitable similar sequences and materials may be used as well.

Also, the metal contact scheme chosen is one that has a planar interface with the semiconductor, after heat treatment to activate the ohmic contact. This is done so that (i) a dielectric layer separating the metal from the semiconductor doesn't have to be deposited and selectively etched in the metal contact areas; and (ii) the contact layer is specularly reflective over the wavelength range of interest.

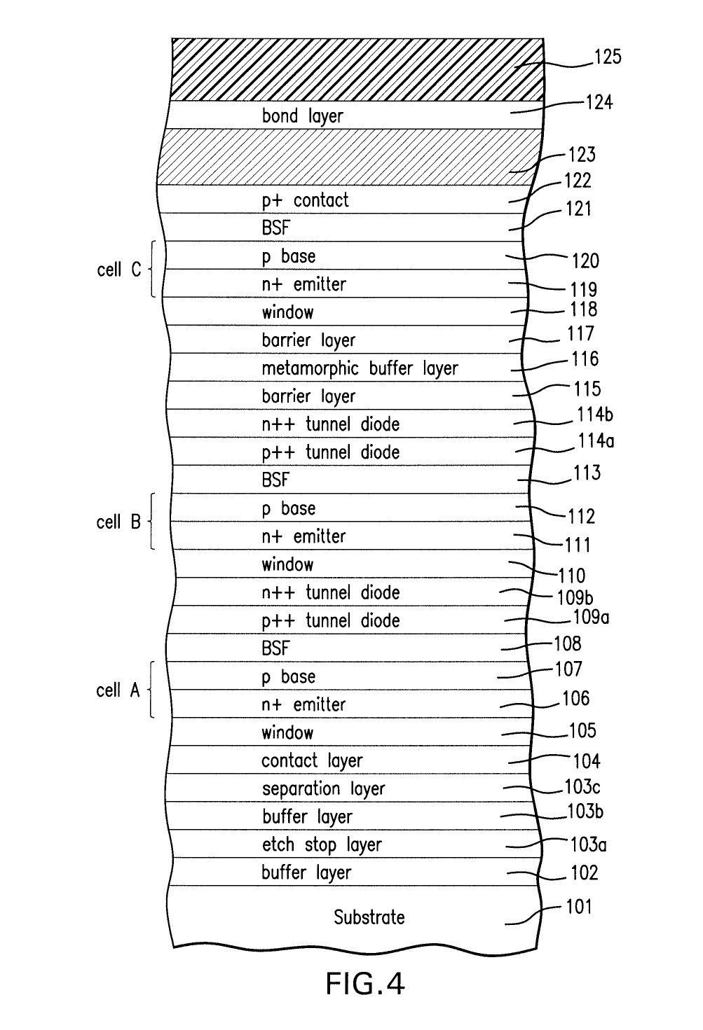

FIG. 4 is a cross-sectional view of the solar cell of FIG. 3 after next process step in which a bonding layer 124 is deposited over the metal layer 123, and the flexible thin film support 125 attached to the contact layer 123 by the bonding layer 124. In one embodiment of the present disclosure, the flexible thin film support is a 50 micron thick Kapton film. In other embodiments, other thicknesses may be employed. In other embodiments, the film 25 may be a polyimide film. In some embodiments, the bonding layer is an adhesive, preferably FEP and PFA, which are DuPont varieties of Teflon. In other embodiments, thermoplastics can also be used as adhesives. The adhesive PFA has a higher melting point (300-310 degrees C.) than FEP (250-280 degrees C.), and may be preferred for some processes. Moreover, PFA can be subject to 260 degrees C. continuous use, while FEP can be subject to 205 degrees C. continuous use. Both of these adhesives are available in films of various thicknesses.

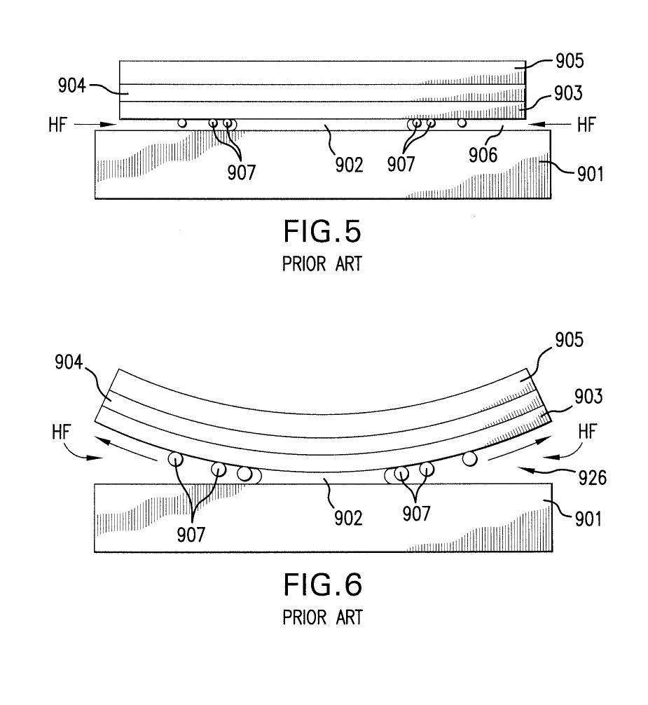

FIG. 5 is a side elevational view showing an epitaxially grown thin film semiconductor device being peeled from an underlying single crystal substrate by a prior art etching technique described in U.S. Pat. Nos. 4,846,931 and 4,883,561. The Figure shows a single crystal GaAs substrate 901 having a thin release film 902 on the surface thereof and epitaxially grown p-type and n-type GaAs layers 903 and 904, forming a p-n junction device, thereon. A support layer 905 (one embodiment being described in U.S. Pat. No. 4,883,561 as the material Apiezon W), overlies the epitaxial layers 903 and 904. Here, as hydroflouric (HF) acid etches the release film 2, a uniformly thick channel 906 forms between the epi-layer 902 and the substrate 901. As etching progresses, the gas reaction product, which has the lowest solubility of any of the reactants or reaction products, is difficult to diffuse away thereby limiting the undercutting speed and the permissible HF acid concentration. If the solubility limits are exceeded, bubbles 907 form at the reaction zone in the channel 906 displacing the etchant and producing a gas pressure which cracks the epitaxial film. Hence, permissible acid concentrations and therefore etch speeds are very low.

FIG. 6 is a side elevational view showing an epitaxially grown thin film semiconductor device being peeled from an underlying single crystal substrate by the etching technique described in prior art U.S. Pat. Nos. 4,846,931 and 4,883,561 in which a support layer 905 is applied so as to be under tension such that as undercutting of the release layer 902 occurs, the film curls with a radius of curvature R thereby forming a non-uniform channel 926 which is wider at the edges than the center of the film.

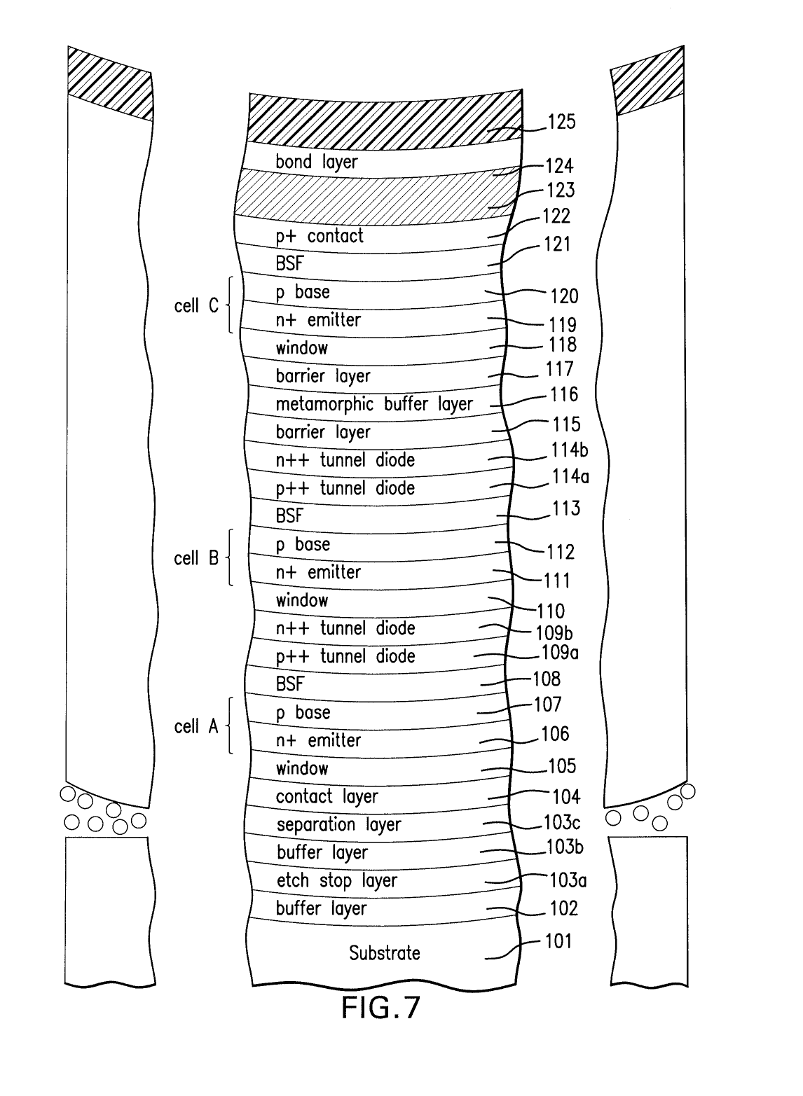

FIG. 7 is an enlarged cross-sectional view of the solar cell during the process of epitaxial lift off according to the present disclosure, showing the outer portion of the separation layer being etched away. In one embodiment, the process entails attaching the thin flexible support at an elevated process temperature (e.g., 180 degrees C.), and subsequently cooling the semiconductor assembly to bring it back to room temperature, preferably for a period of about ten minutes. During the cooling step, the difference in the coefficient of thermal expansion of the thin flexible support (around 20 ppm/degree C.) and the semiconductor material (around 6 ppm/degree C.) results in the curling back of the thin flexible support and the attached layers of semiconductor material as they separate from the substrate. In another embodiment, the process entails etching the separation layer while cooling so that the support and the attached layers curls away as they separate from the substrate.

In another embodiment, the semiconductor structure is immersed in a container holding a suitable solvent or etchant solution Air suction is then applied to the top of the container, causing the pliable flexible support 125 and the attached layers 104 through 124 to experience a force which increases with the distance from the center, so that along the periphery of the sides of the flexible support 125 is pulled up and away from the substrate 101 and its associated layers 102 through 103b. This allows a solvent or etchant solution to penetrate into the separation layer 103c and react with it, as indicated in the Figure by the formation of bubbles or reaction products 208, which push upward on the flexible support 125 and the attached layers 104 through 124, allowing them to be separated and released from the separation layer 103c by virtue of the curling force and the moving solvent solution.

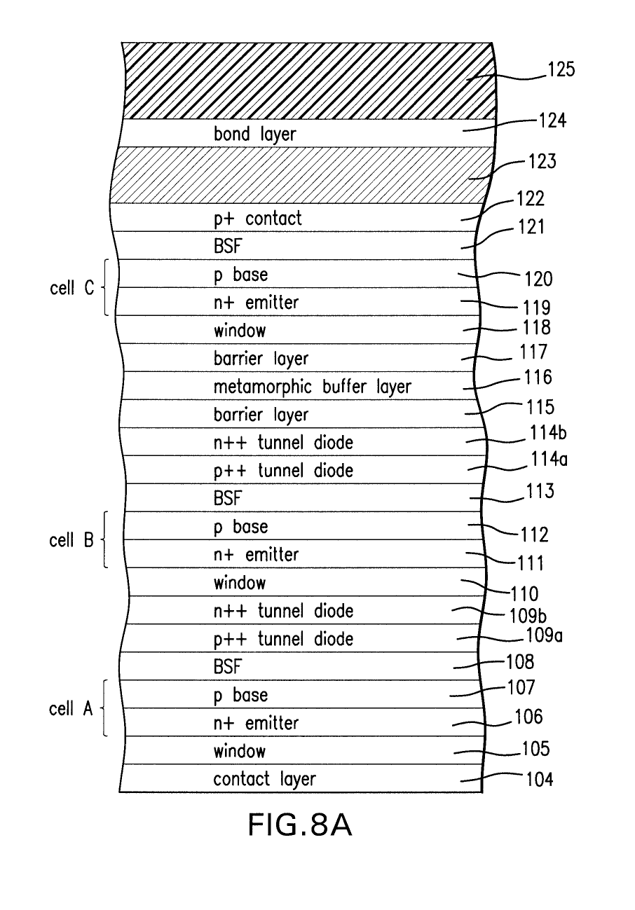

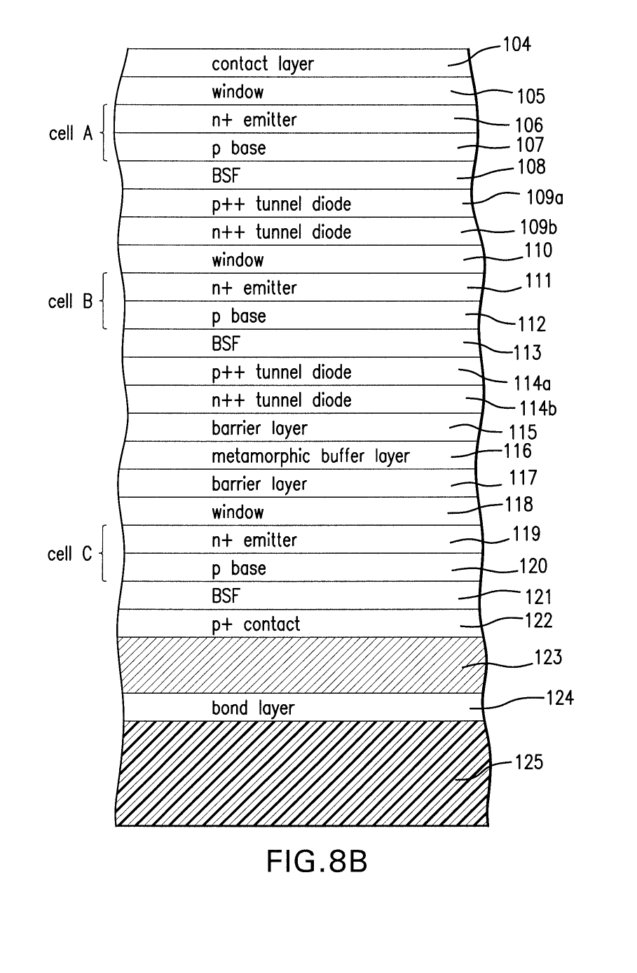

FIG. 8A is a cross-sectional view of the solar cell of FIG. 4 after the process steps in which the original substrate is removed by the techniques described above.

FIG. 8B is a cross-sectional view of the solar cell of FIG. 8A with the orientation with the flexible support 125 being at the bottom of the Figure. Subsequent Figures in this application will assume such orientation.

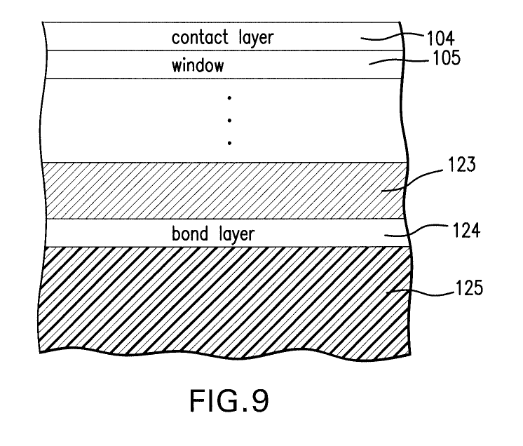

FIG. 9 is a simplified cross-sectional view of the solar cell of FIG. 8B depicting just a few of the top layers and lower layers over the flexible support 125.

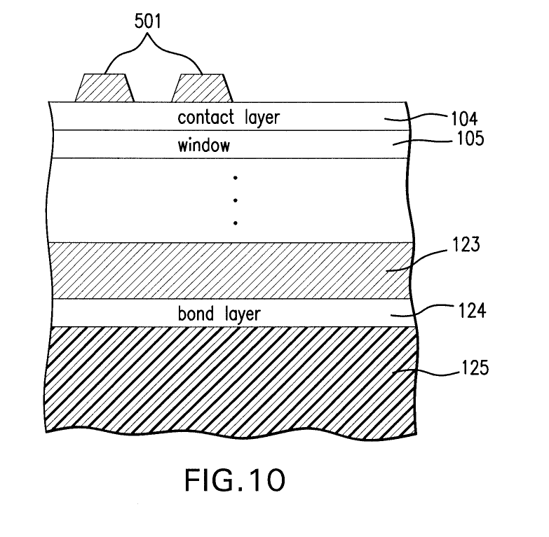

FIG. 10 is a cross-sectional view of the solar cell of FIG. 9 after the next sequence of process steps in which a photoresist mask (not shown) is placed over the contact layer 104 to form the grid lines 501. As will be described in greater detail below, the grid lines 501 are deposited via evaporation and lithographically patterned and deposited over the contact layer 104. The mask is subsequently lifted off to form the finished metal grid lines 501 as depicted in the Figures.

As more fully described in U.S. patent application Ser. No. 12/218,582 filed Jul. 18, 2008, hereby incorporated by reference, the grid lines 501 are preferably composed of the sequence of layers Pd/Ge/Ti/Pd/Au, although other suitable sequences and materials may be used as well.

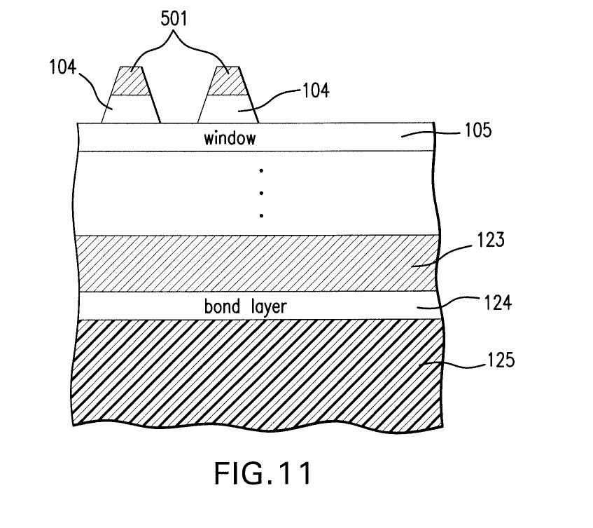

FIG. 11 is a cross-sectional view of the solar cell of FIG. 10 after the next process step in which the grid lines are used as a mask to etch down the surface to the window layer 105 using a citric acid/peroxide etching mixture.

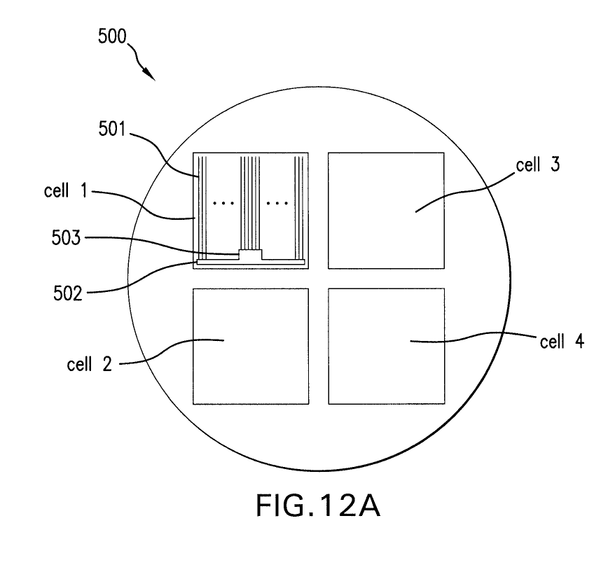

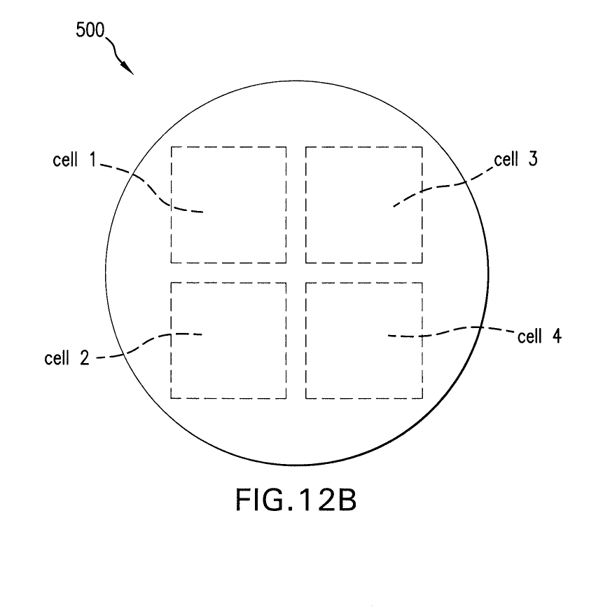

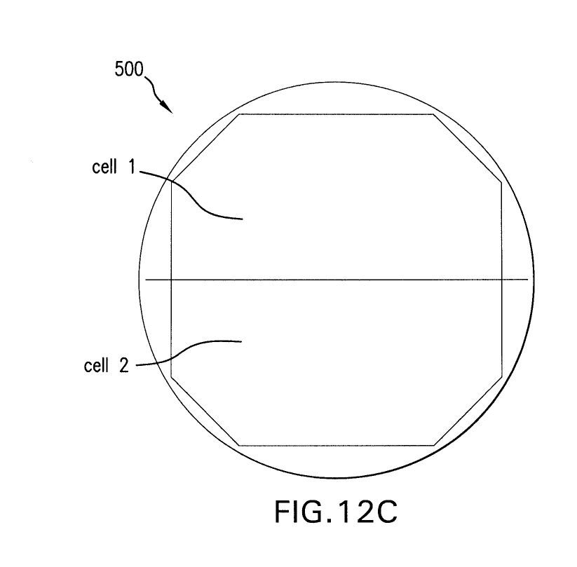

FIG. 12A is a top plan view of a 100 mm (or 4 inch) wafer in which four solar cells are implemented. The depiction of four cells is for illustration for purposes only, and the present disclosure is not limited to any specific number of cells per wafer.

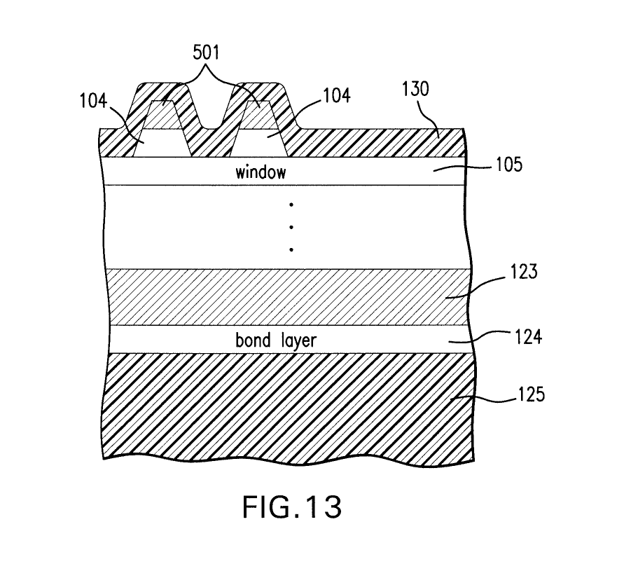

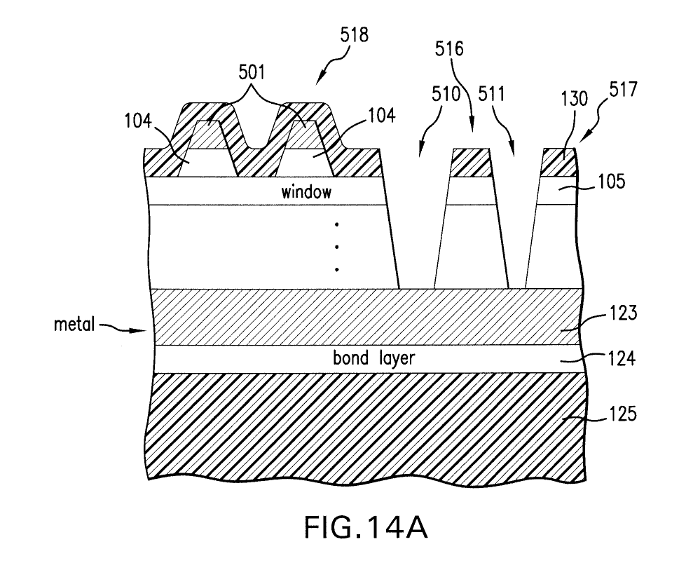

In each cell there are grid lines 501 (more particularly shown in cross-section in FIG. 13), an interconnecting bus line 502, and a contact pad 503. The geometry and number of grid and bus lines and the contact pad are illustrative and the present disclosure is not limited to the illustrated embodiment.

FIG. 12B is a bottom plan view of the wafer of FIG. 12A.

FIG. 12C is a top plan view of a 100 mm (or 4 inch) wafer in which two solar cells are implemented. Each solar cell has an area of 26.3 cm² and a power/weight ratio (after separation from the growth substrate, and including a 4 mil thick cover glass) of 945 mW/g.

FIG. 13 is a cross-sectional view of the solar cell of FIG. 11 after the next process step in which an antireflective (ARC) dielectric coating layer 130 is applied over the entire surface of the “top” side of the cell with the grid lines 501.

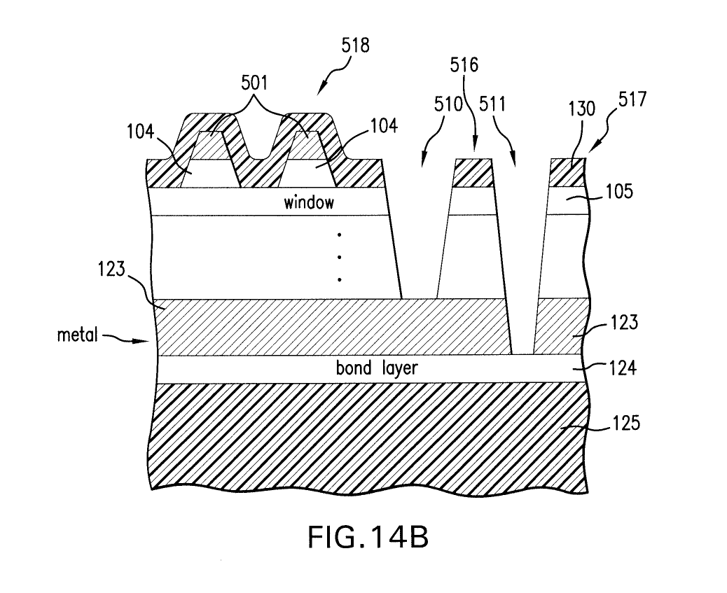

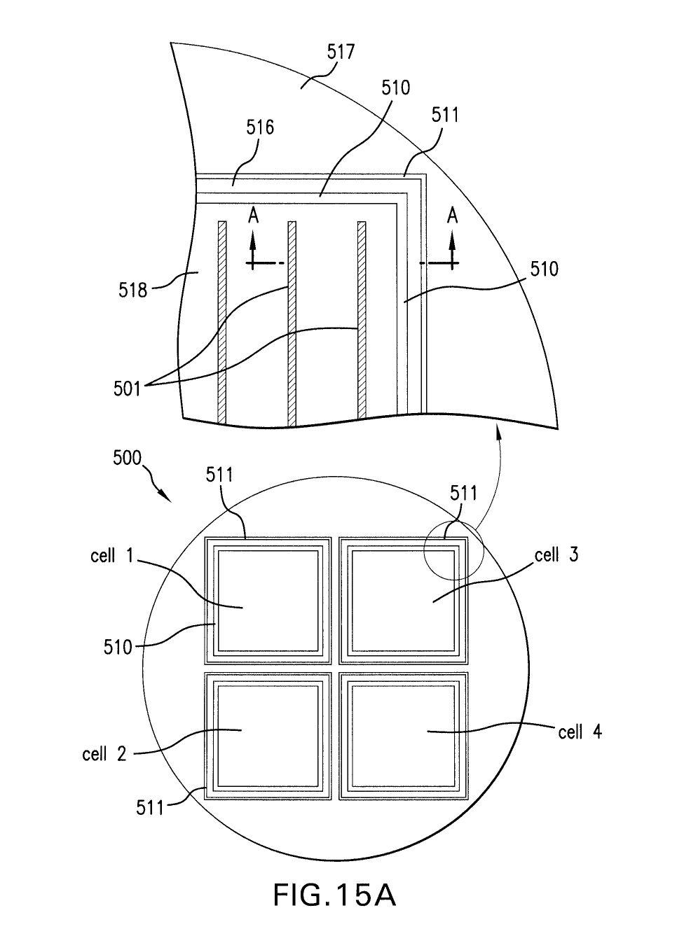

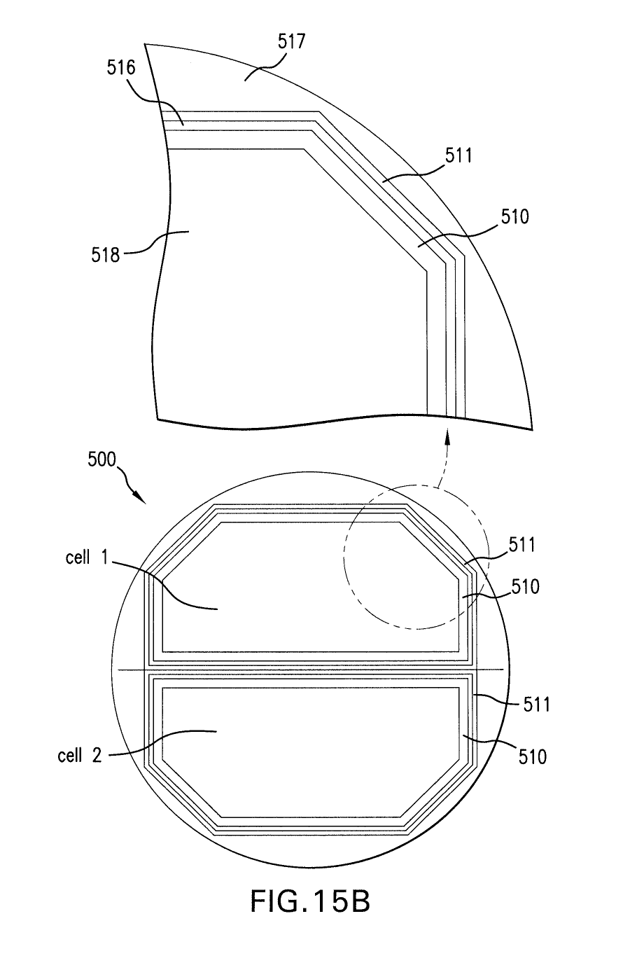

FIG. 14A is a cross-sectional view of the solar cell of FIG. 13 after the next process step according to the present disclosure in which first and second annular channels 510 and 511, or portion of the semiconductor structure are etched down to the metal layer 123 using phosphide and arsenide etchants. These channels, as more particularly described in U.S. patent application Ser. No. 12/190,449 filed Aug. 12, 2008, define a peripheral boundary between the cell and the rest of the wafer, and leave a mesa structure which constitutes the solar cell. The cross-section depicted in FIG. 14A is that as seen from the A-A plane shown in FIG. 15A. In a preferred embodiment, channel 510 is substantially wider than that of channel 511.

FIG. 14B is a cross-sectional view of the solar cell of FIG. 14A after the next process step in which channel 511 is exposed to a metal etchant, layer 123 in the channel 511 is removed, and channel 511 is extended in depth approximately to the top surface of the adhesive layer 124.

FIGS. 15A and 15B are top plan views of the wafer of FIGS. 12A and 12C, respectively, depicting the channels 510 and 511 etched around the periphery of each cell.

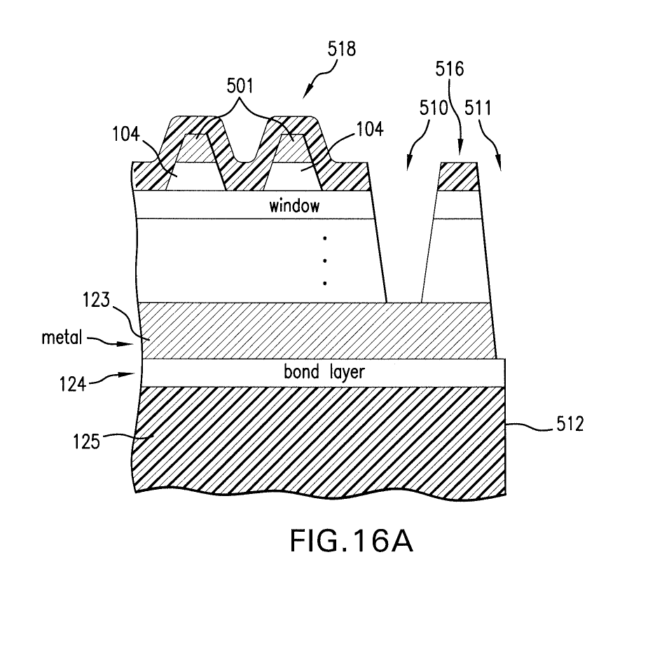

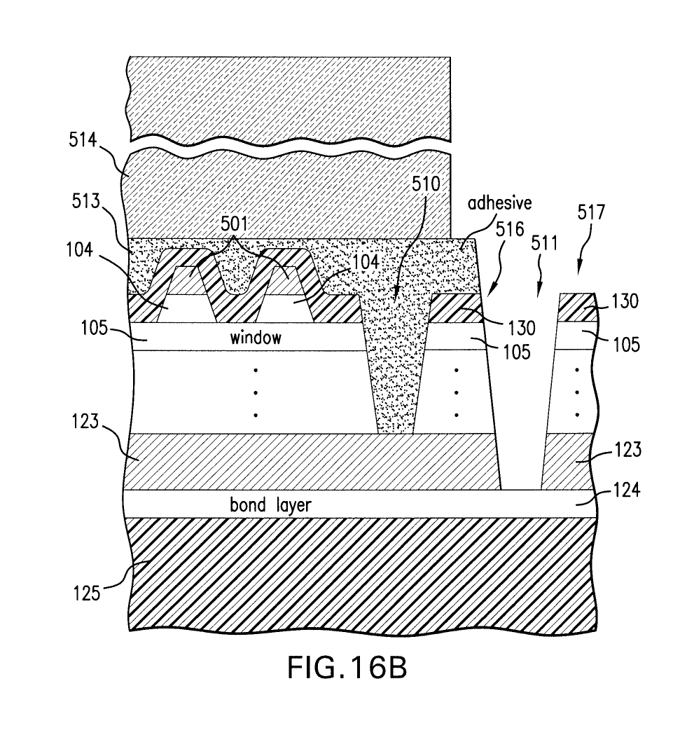

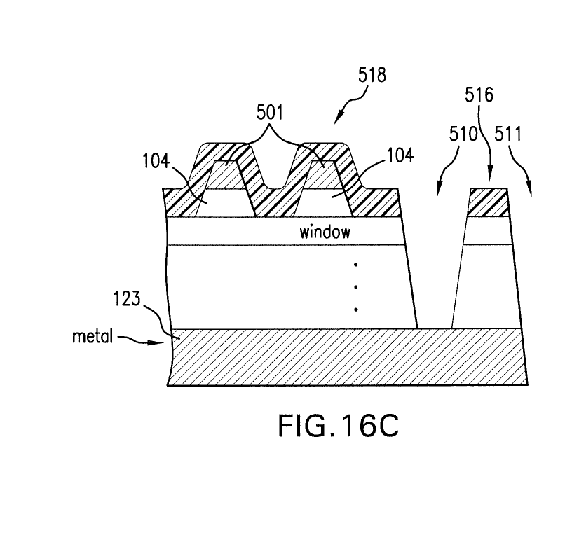

FIG. 16A is a cross-sectional view of the solar cell of FIG. 14B after the individual solar cells (cell 1, cell 2, etc. shown in FIG. 15A) are cut or scribed from the wafer through the channel 511, leaving a vertical edge 512 extending through the flexible support 125. In this first embodiment of the present disclosure, the surrogate substrate 125 forms the support for the solar cell in applications where a cover glass (such as provided in the third embodiment to be described below) is not required. In such an embodiment, electrical contact to the metal contact layer 123 may be made through the channel 510.

FIG. 16B is a cross-sectional view of the solar cell of FIG. 14B after the next process step in another embodiment of the present disclosure in which a cover glass 514 is secured to the top of the cell by an adhesive 513. The cover glass 514 is typically about 4 mils thick and preferably covers the entire channel 510, but does not extend to channel 511. Although the use of a cover glass is desirable for many environmental conditions and applications, it is not necessary for all implementations, and additional layers or structures may also be utilized for providing additional support or environmental protection to the solar cell.

FIG. 16C is a cross-sectional view of the solar cell of FIG. 16A after the next process step in an embodiment of the present disclosure in which the flexible support 125 is removed.

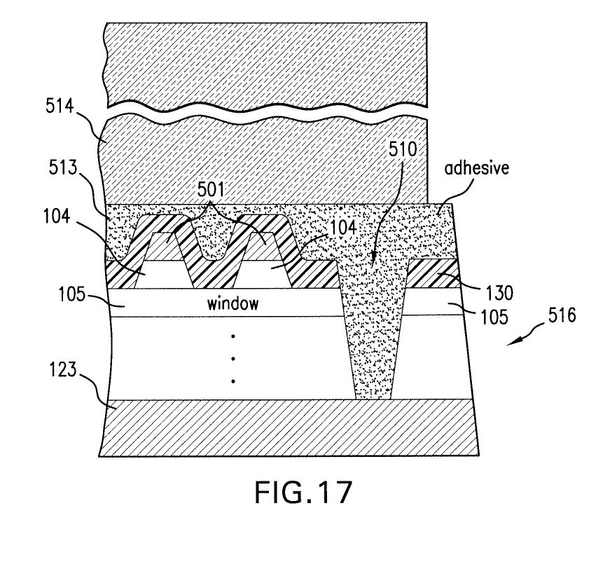

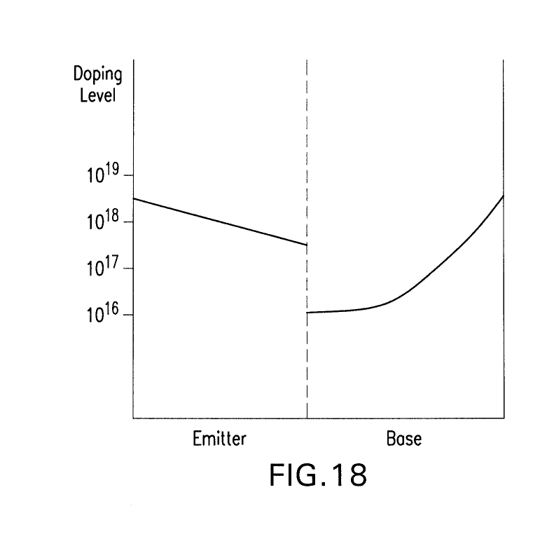

FIG. 17 is a cross-sectional view of the solar cell of FIG. 18C after the next process step in some embodiments of the present flexible support in which the adhesive layer 124, the flexible support 125 and the peripheral portion 512 of the wafer is entirely removed, leaving only the solar cell with the cover glass 514 (or other layers or structures) on the top, and the metal contact layer 123 on the bottom, which forms the backside contact of the solar cell.

FIG. 18 is a graph of a doping profile in the emitter and base layers in one or more subcells of the inverted metamorphic multijunction solar cell of the present disclosure. The various doping profiles within the scope of the present disclosure and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

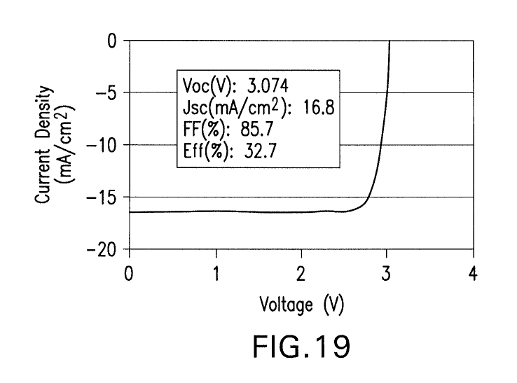

FIG. 19 is a graph that depicts the current and voltage characteristics of the solar cell according to the present disclosure. The solar cell has an open circuit voltage (V_{oc}) of approximately 3.074 volts, a short circuit current of approximately 16.8 mA/cm², a fill factor of approximately 85.7%, and an efficiency of 32.7%.

It will be understood that each of the elements described above, or two or more together, also may find a useful application in other types of constructions differing from the types of constructions described above.

Although the preferred embodiment of the present disclosure utilizes a vertical stack of three subcells, the present invention can apply to stacks with fewer or greater number of subcells, i.e. two junction cells, four junction cells, five junction cells, etc. as more particularly described in U.S. patent application Ser. No. 12/267,812 filed Nov. 10, 2008. In the case of four or more junction cells, the use of more than one metamorphic grading interlayer may also be utilized, as more particularly described in U.S. patent application Ser. No. 12/271,192 filed Nov. 14, 2008.

In addition, although the present embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the solar cell of the present disclosure may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772 filed Jan. 31, 2008, the solar cell of the present disclosure may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or the emitter layer may also be intrinsic or not-intentionally-doped (“NID”) over part or all of its thickness. Some such configurations are more particularly described in copending U.S. patent application Ser. No. 12/253,051, filed Oct. 16, 2008.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AIN, GaN, InN, GaInN, AlGaInN, GaInNAs, AlGaInNAs, ZnSSe, CdSSe, and similar materials, and still fall within the spirit of the present disclosure.

While the invention has been illustrated and described as embodied in an inverted metamorphic multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as, thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method for selectively freeing an epitaxial layer from a single crystal substrate upon which it was grown, comprising:
providing a first substrate;
depositing a separation layer on said first substrate;
depositing on said separation layer a sequence of layers of semiconductor material forming a solar cell;
mounting and bonding a thin flexible support having a coefficient of thermal expansion substantially greater than that of the adjacent semiconductor material on top of the sequence of layers at an elevated temperature; and
etching said separation layer while the temperature of the support and layers of semiconductor material decreases, so that the support and the attached layer curls away from said first substrate in view of the difference in the coefficient of thermal expansion of the support and the adjacent semiconductor material.

2. A method as defined in claim 1, wherein the decrease in temperature allows said epitaxial layer and the thin flexible support to curl upward, permitting the outdiffusion from the separation layer of reaction products of the etching process.

3. A method as defined in claim 1, wherein the first substrate is composed of gallium arsenide.

4. A method as defined in claim 1, wherein said separation layer is approximately 100 Angstroms in thickness.

5. A method as defined in claim 1, wherein said separation layer is composed of GaAlAs.

6. A method as defined in claim 1, wherein said thin flexible support is composed of a polyimide material.

7. A method as defined in claim 1, wherein the depositing a sequence of layers comprises:
forming a first subcell comprising a first semiconductor material with a first band gap and a first lattice constant;
forming a second subcell comprising a second semiconductor material with a second band gap and a second lattice constant, wherein the second band gap is less than the first band gap and the second lattice constant is greater than the first lattice constant to the second lattice constant; and
forming a lattice constant transition material positioned between the first subcell and the second subcell, said lattice constant transition material having a lattice constant that changes gradually from the first lattice constant to the second lattice constant.

8. A method as defined in claim 7, wherein said transition material is composed of any of the As P, N, Sb based II-V compound semiconductors subject to the constraints of having the in-plane lattice parameter greater or equal to that of the first subcell and less than or equal to that of the second subcell, and having a band gap energy greater than that of the second subcell, and the band gap of the transition material remains constant at approximately 1.50 eV throughout its thickness.

9. A method as defined in claim 7, wherein said transition material is composed of (InₓGa₁₋ₓ)_{y}Al_{1-y}As with x and y selected such that the band gap of each interlayer remains constant throughout its thickness.

10. A method as defined in claim 7, wherein said first subcell is composed of an GaInP, GaAs, GaInAs, GaAsSb, or GaInAsN emitter region and an InGaP, GaAs, GaInAs, GaAsSb, or GaInAsN base region, and the second subcell is composed of an InGaP emitter layer and a GaAs or GaInAs base layer.

11. A method as defined in claim 1, wherein depositing a sequence of layers comprises:
forming an upper first solar subcell on said first substrate having a first band gap;
forming a middle second solar subcell over said first solar subcell having a second band gap smaller than said first band gap;
forming a graded interlayer over said second solar cell; and
forming a lower third solar subcell over said graded interlayer having a fourth band gap smaller than said second band gap such that said third subcell is lattice mismatched with respect to said second subcell.

12. A method as defined in claim 11, wherein the upper subcell is composed of InGa(Al)P.

13. A method as defined in claim 11, wherein the middle subcell is composed of an GaAs, GaInP, GaInAs, GaAsSb, or GaInAsN emitter region and a GaAs, GaInAs, GaAsSb, or GaInAsN base region.

14. A method as defined in claim 11, wherein the lower solar subcell is composed of an InGaAs base and emitter layer, or a InGaAs base layer and a InGaP emitter layer.

15. A method as defined as claim 11, wherein the graded interlayer is compositionally graded to lattice match the middle subcell on one side and the lower subcell on the other side, and is composed of (InₓGa₁₋ₓ)_{y}Al_{1-y}As with x and y selected such that the band gap of the interlayer remains constant throughout its thickness and greater than said second band gap.

16. A method as defined in claim 15, wherein the graded interlayer has approximately a 1.5 eV band gap throughout its thickness.

17. A method as defined in claim 11, wherein the graded interlayer is composed of any of the As, P, N, Sb based III-V compound semiconductors subject to the constraints of having the in-plane lattice parameter greater or equal to that of the second solar cell and less than or equal to that of the second solar cell and less than or equal to that of the third solar cell, and having a band gap energy greater than that of the second solar cell.

18. The method as defined in claim 1, wherein the coefficient of thermal expansion of the flexible support is around 20 ppm/degree C.

19. The method as defined in claim 1, wherein the flexible support is composed of Kapton and approximately 50 microns in thickness.

20. A method for selectively freeing an epitaxial layer from a single crystal substrate upon which it was grown, comprising:
providing a substrate;
depositing a separation layer on the substrate;
depositing on the separation layer a sequence of epitaxial layers of semiconductor material forming a semiconductor device;
mounting and bonding a thin flexible support on top of the sequence of layers; and
subsequently processing the substrate at decreasing temperature so that the difference in the coefficient of thermal expansion of the thin flexible support and the semiconductor material results in the curling back of the thin flexible support and the layers of semiconductor material as they separate from the substrate.
